(19) United States
(12) Patent Application Publication
(10) Pub. No.: US 2015/0061114 A1
(43) Pub. Date: Mar. 5, 2015

(54) SEMICONDUCTOR DEVICE AND METHOD OF MANUFACTURING THE SAME

(71) Applicant: TOYOTA JIDOSHA KABUSHIKI KAISHA, Toyota-shi (JP)

(72) Inventor: Katsutoshi NARITA, Toyota-shi (JP)

(21) Appl. No.: 14/456,654

(22) Filed: Aug. 11, 2014

(30) Foreign Application Priority Data
Sep. 2, 2013 (JP) 2013-181409

(51) Int. Cl. H01L 23/00; H01L 23/485; H01L 21/28; H01L 23/495

(52) U.S. Cl. CPC H01L 23/564; H01L 23/49562; H01L 23/485; H01L 21/28
USPC 257/734; 438/652

(57) ABSTRACT

A semiconductor device includes a semiconductor chip and a joined member. The semiconductor chip has a semiconductor substrate, a first electrode, and a second electrode. The first electrode is arranged on a first surface of the semiconductor substrate. The second electrode is arranged on a second surface of the semiconductor substrate. The first electrode is joined to the joined member via a joint material. A tensile force in a surface direction of the first surface that is applied to the first surface of the semiconductor substrate from the first electrode due to thermal expansion of the first electrode at a melting temperature of the joint material is at least equal to a tensile force in the surface direction that is applied to the second surface of the semiconductor substrate from the second electrode due to thermal expansion of the second electrode at the melting temperature.

### INCORPORATION BY REFERENCE

The disclosure of Japanese Patent Application No. 2013-181409 filed on Sep. 2, 2013 including the specification, drawings and abstract is incorporated herein by reference in its entirety.

### BACKGROUND OF THE INVENTION

1. Field of the Invention

The present invention relates to a semiconductor device and a method of manufacturing the same.

2. Description of Related Art

A semiconductor device has been known in which a connection conductor and the like are joined to a semiconductor chip by soldering. For example, a semiconductor device disclosed in Japanese Patent Application Publication No. 2005-051084 (JP 2005-051084 A) includes a semiconductor chip and a lead frame (an example of the connection conductor). The semiconductor chip includes a semiconductor substrate, a front surface electrode that is formed on a front surface of the semiconductor substrate, and a back surface electrode that is formed on a back surface of the semiconductor substrate. The lead frame is joined to the front surface electrode of the semiconductor chip by soldering, and a circuit pattern on the substrate is joined to the back surface electrode by soldering.

In a case where a joined member such as the lead frame is joined to the semiconductor chip, which is formed with the electrodes on both of the surfaces, by a joint material such as solder as disclosed in JP 2005-051084 A, the semiconductor chip may be warped upon joining of the joined member to the semiconductor chip by the joint material. In general, linear expansion coefficients of the front surface electrode and the back surface electrode are larger than a linear expansion coefficient of the semiconductor substrate. Thus, when the semiconductor chip is heated for solder joining, the front surface electrode and the back surface electrode intend to expand thermally in a manner to become larger than the semiconductor substrate. Accordingly, a tensile force in a surface direction by the front surface electrode is applied to the front surface of the semiconductor substrate, and a tensile force in the surface direction by the back surface electrode is applied to the back surface of the semiconductor substrate. When the tensile force that is applied to the front surface of the semiconductor substrate differs from the tensile force that is applied to the back surface of the semiconductor substrate, a warp of the semiconductor chip occurs. In this case, if a surface of the semiconductor chip that is joined by soldering is warped in a concave shape or in a waveform with respect to the joined member, a bubble may be mixed in the solder between the semiconductor chip and the joined member. If the bubble is mixed during solder joining, solder joining is carried out with the bubble remaining in the solder, and this may affect an electrical characteristic of the semiconductor device.

### SUMMARY OF THE INVENTION

The present invention provides a technique of suppressing a bubble from being formed in a joint material when a joined member is joined to one surface of a semiconductor chip by using a joint material.

A semiconductor device according to a first aspect of the present invention includes a semiconductor chip and a joined member. The semiconductor chip has a semiconductor substrate, a first electrode, and a second electrode. The first electrode is arranged on a first surface of the semiconductor substrate. The second electrode is arranged on a second surface of the semiconductor substrate. The first electrode and the second electrode have larger linear expansion coefficients than a linear expansion coefficient of the semiconductor substrate. The first electrode is joined to the joined member via a joint material. A tensile force in a surface direction of the first surface that is applied to the first surface of the semiconductor substrate from the first electrode due to thermal expansion of the first electrode at a melting temperature of the joint material is at least equal to a tensile force in the surface direction that is applied to the second surface of the semiconductor substrate from the second electrode due to thermal expansion of the second electrode at the melting temperature.

In the semiconductor device of the first aspect of the present invention, the tensile force that is applied to the first surface of the semiconductor substrate from the first electrode due to thermal expansion of the first electrode at a melting temperature of the joint material is at least equal to the tensile force that is applied to the second surface of the semiconductor substrate from the second electrode due to thermal expansion of the second electrode. Thus, when the semiconductor chip is heated to the melting temperature of the joint material, the semiconductor chip obtains a shape in which a surface formed with the first electrode (hereinafter also referred to as “the first surface of the semiconductor chip”) is warped to project to the joined member side or is flat. When the semiconductor chip is in a convex shape, a center portion (that is, a portion that is projected in the convex shape) of the first surface of the semiconductor chip is brought into contact with the joint material. On the other hand, when the semiconductor chip is in a flat shape, the entire first surface of the semiconductor chip is brought into contact with the joint material. In the above-described semiconductor device, the joint material is melted at the melting temperature and hardens thereafter. Accordingly, the first surface of the semiconductor chip (that is, the first electrode) is joined to the joined member. When the semiconductor chip is in the convex shape with respect to the joined member at the melting temperature of the joint material, the melted joint material spreads wetly from a contact portion (that is, a center portion of the first surface of the semiconductor chip) with the first surface of the semiconductor chip. Thus, a bubble is less likely to be mixed in the joint material in a joining procedure, and formation of the bubble in the joint material upon joining can be suppressed. Similarly, when the semiconductor chip is in the flat shape at the melting temperature of the joint material, the melted joint material spreads wetly to the entire first surface of the semiconductor chip. Thus, the bubble is less likely to be incorporated in the joint material in the joining procedure, and the formation of the bubble in the joint material upon joining can be suppressed.

A method of manufacturing a semiconductor device according to a second aspect of the present invention includes: preparing a semiconductor substrate that is formed with a semiconductor element structure; preparing a semiconductor chip by forming a first electrode on a first surface of the semiconductor substrate and by forming a second electrode on a second surface of the semiconductor substrate; introducing a joined member on which the semiconductor chip is arranged into a furnace in a state that the first electrode of the semiconductor chip faces the first surface of the joined member via a joint material; heating an inside of the furnace at least to a melting temperature of the joint material to melt the joint material; cooling the joint member, on which the semiconductor chip is arranged, and hardening the joint material to join the first electrode of the semiconductor chip to the first surface of the joined member; preparing the first electrode that is configured to apply a first tensile force due to thermal expansion of the first electrode to the first surface of the semiconductor substrate at the melting temperature of the joint material when the inside of the furnace is heated; and preparing the second electrode that is configured to apply a second tensile force due to thermal expansion of the second electrode to the second surface of the semiconductor substrate at the melting temperature of the joint material when the inside of the furnace is heated. The first tensile force is at least equal to the second tensile force. According to a method of manufacturing of the second aspect of the present invention, when the joint material is used to join the joined member to one surface of the semiconductor chip, it is possible to manufacture the semiconductor device in which the bubble is less likely to be formed in the joint material.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a vertical cross-sectional view of a semiconductor device in a first embodiment of the present invention;

FIG. 2 is a vertical cross-sectional view of a semiconductor chip in a comparative example 1;

FIG. 3 shows a procedure of joining a lead frame by soldering to a back surface electrode of a semiconductor chip in the comparative example 1 by a reflow soldering method;

FIG. 4 shows a procedure of joining a lead frame by soldering to a back surface electrode of a semiconductor chip in the first embodiment of the present invention by the reflow soldering method;

FIG. 5 is a vertical cross-sectional view of a semiconductor chip in a second embodiment of the present invention;

FIG. 6 is a vertical cross-sectional view of a semiconductor chip in a third embodiment of the present invention;

FIG. 7 is a vertical cross-sectional view of a semiconductor chip in a fourth embodiment of the present invention;

FIG. 8 is a plan view of the semiconductor chip in the fourth embodiment of the present invention;

FIG. 9 is a vertical cross-sectional view of a semiconductor chip of a comparative example 2;

FIG. 10 shows a procedure of joining a lead frame by soldering to a back surface electrode of the semiconductor chip in the comparative example 2 by the reflow soldering method;

FIG. 11 is a view that illustrates a method of manufacturing the semiconductor device in the first embodiment of the present invention and shows a state that an electrode and an insulation layer are formed on a semiconductor substrate;

FIG. 12 is a view that illustrates the method of manufacturing the semiconductor device in the first embodiment of the present invention and shows the semiconductor chip and the lead frame that are introduced into a reflow furnace;

FIG. 13 is a view that illustrates the method of manufacturing the semiconductor device in the first embodiment of the present invention and shows the semiconductor chip and the lead frame when an inside of the reflow furnace is heated;

FIG. 14 is a view that illustrates the method of manufacturing the semiconductor device in the first embodiment of the present invention and shows the semiconductor chip and the lead frame when the inside of the reflow furnace reaches a solder melting temperature; and

FIG. 15 is a view that illustrates the method of manufacturing the semiconductor device in the first embodiment of the present invention and shows a state that the reflow furnace is cooled and the lead frame is joined to the back surface electrode of the semiconductor chip by soldering.

### DETAILED DESCRIPTION OF EMBODIMENTS

Primary features of embodiments, which will be described below, will be listed here. It should be noted that technical elements described below are independent of each other, and demonstrate technical utility when used singly or in various combinations. These technical features may appropriately be combined for use.

In the semiconductor device of the embodiments of the invention, a thickness of the first electrode in a stacking direction of the semiconductor chip may be at least equal to a thickness of the second electrode. According to this configuration, a volume of the first electrode is larger than a volume of the second electrode. Thus, the tensile force of the first electrode and the tensile force of the second electrode can easily be controlled such that the tensile force that is applied to the first surface of the semiconductor substrate from the first electrode due to thermal expansion of the first electrode at the melting temperature of the joint material is larger than the tensile force that is generated and applied to the second surface of the semiconductor substrate from the second electrode due to thermal expansion of the second electrode.

In the semiconductor device of the embodiments of the invention, the linear expansion coefficient of the first electrode may be at least equal to the linear expansion coefficient of the second electrode. According to this configuration, the first electrode is more likely to expand in conjunction with a temperature increase than the second electrode. Thus, the tensile force of the first electrode and the tensile force of the second electrode can easily be controlled such that the semiconductor chip is warped in a convex shape on a joined member side or is in a flat shape at the melting temperature of the joint material.

In the semiconductor device of the embodiments of the invention, a front surface area of the first electrode in the surface direction may be at least equal to a front surface area of the second electrode in the surface direction. According to this configuration, due to a large surface area, the first electrode expands to be larger than the second electrode. Thus, the tensile force of the first electrode and the tensile force of the second electrode can easily be controlled such that the semiconductor chip is warped in the convex shape on the joined member side or is in the flat shape at the melting temperature of the joint material.

In the semiconductor device of the embodiments of the invention, at least one of the first electrode and the second electrode may be constituted by a single layer or plural layers. According to this configuration, the joined member, a connection conductor, and the like can appropriately be connected to the first surface and/or the second surface of the semiconductor chip.

In the semiconductor device of the embodiments of the invention, the second electrode may include a first layer and a second layer. The first layer may include a plurality of portions, the portions being arranged on the second surface of the semiconductor substrate and being separated from each other. An insulation layer may be arranged between the portions which are adjacent to each other. The second layer may cover an exposed surface of each of the portions of the first layer and at least part of an exposed surface of the insulation layer and be arranged over each of the portions of the first layer and the insulation layer. A linear expansion coefficient of the second layer may be at most equal to a linear expansion coefficient of the first layer and a linear expansion coefficient of the insulation layer. According to this configuration, the second layer suppresses the first layer and the insulation layer from expanding thermally by the different linear expansion coefficients in conjunction with the temperature increase. In other words, application of the tensile forces that differ by positions to the second surface of the semiconductor substrate is suppressed. Thus, deformation of the semiconductor chip in a waveform (that is, a local warp thereof in a concave shape with respect to the joined member) is suppressed, and formation of a bubble in the joint material can be suppressed.

In the method of manufacturing the semiconductor device of the embodiments of the invention, the second electrode may be constituted by a first layer and a second layer. The first layer may be constituted by a plurality of portions that are formed on the second surface of the semiconductor substrate and are separated from each other. An insulation layer may be formed between the portions which are adjacent to each other. The second layer may be formed of a material that has a linear expansion coefficient that is at most equal to linear expansion coefficients of materials of which the first layer and the insulation layer are respectively formed. An exposed surface of the first layer and at least part of an exposed surface of the insulation layer may be covered with the second layer by a mask sputtering method. According to this method of manufacturing, it is possible to manufacture a semiconductor device in which the bubble is unlikely to be formed in the joint material when the first surface of the semiconductor chip is joined to the joined member by using the joint material.

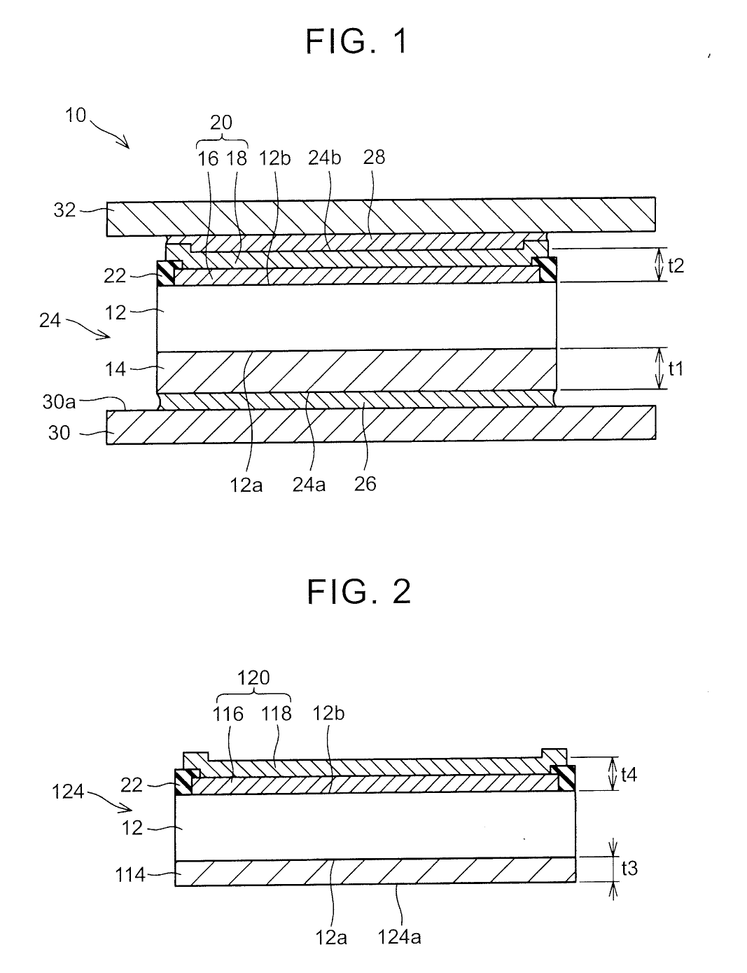

A description will be made on a semiconductor device 10 of this embodiment. As shown in FIG. 1, the semiconductor device 10 includes a semiconductor substrate 12. The semiconductor substrate 12 is formed with a semiconductor element structure of insulation gate type. An Si substrate is used for the semiconductor substrate 12. A back surface electrode 14 is formed on a back surface 12a of the semiconductor substrate 12. The back surface electrode 14 is formed of four layers of metal films, and includes an Al film, a Ti film, an Ni film, and an Au film in this order from the back surface 12a side. The back surface electrode 14 functions as a collector electrode. Meanwhile, a front surface 12b of the semiconductor substrate 12 is formed with a front surface electrode 16. AlSi is used for the front surface electrode 16. An insulation layer 22 is formed on an outer periphery of the front surface electrode 16. The insulation layer 22 covers end surfaces of the front surface electrode 16 and part of a front surface of the outer periphery of the front surface electrode 16. Polyimide is used for the insulation layer 22. A front surface electrode 18 is formed on the front surface of the front surface electrode 16 and part of a front surface of the insulation layer 22. The front surface electrode 18 is formed across the front surface electrode 16 and the insulation layer 22. The front surface electrode 18 is formed of two layers of the metal films, and is constituted by the Ni film and the Au film in this order from the front surface side of the front surface electrode 16 and the insulation layer 22. A metal electrode 20 is constituted by the front surface electrode 16 and the front surface electrode 18. The metal electrode 20 functions as an emitter electrode. The semiconductor substrate 12, the back surface electrode 14, the metal electrode 20, and the insulation layer 22 constitute a semiconductor chip 24 that functions as an IGBT. In this embodiment, a thickness t1 of the back surface electrode 14 (a thickness in a stacking direction (a vertical direction in FIG. 1) of the semiconductor chip 24) is set to be larger than a thickness t2 of the metal electrode 20 (which will be described below). Here, the back surface electrode 14 may be regarded as the first electrode of the present invention. The metal electrode 20 may be regarded as the second electrode of the present invention. In addition, the back surface 12a of the semiconductor substrate 12 may be regarded as the first surface of the semiconductor substrate of the present invention. The front surface 12b may be regarded as the second surface of the semiconductor substrate of the present invention.

A lead frame 30 is joined to the back surface electrode 14 (that is, a back surface 24a of the semiconductor chip 24) via solder 26. Similarly, a lead frame 32 is joined to the metal electrode 20 (that is, a front surface 24b of the semiconductor chip 24) via solder 28. Although it will be described in detail below, a reflow soldering method is used for solder joining in this embodiment. Although Cu is used for each of the lead frames 30, 32, a material used for the lead frames is not limited thereto. The semiconductor chip 24 and the lead frames 30, 32 are integrally sealed by a thermosetting resin (not shown) such as an epoxy resin. The semiconductor device 10 is configured just as described. In other words, the semiconductor device 10 is a semiconductor device of double-sided joint type. Here, the solder 26 may be regarded as the joint material of the present invention. The lead frame 30 may be regarded as the joined member of the present invention. A front surface 30a of the lead frame 30 may be regarded as the first surface of the joined member of the present invention.

Next, a description will be made on a magnitude relationship in linear expansion coefficient among the semiconductor substrate 12, the back surface electrode 14, and the metal electrode 20, which constitute the semiconductor chip 24 at 20[° C.]. A linear expansion coefficient of Si, which constitutes the semiconductor substrate 12, is about 2.6 [ppm/K]. Linear expansion coefficients of Al, Ti, Ni, and Au, which constitute the back surface electrode 14, are respectively about 23 [ppm/K], 8.6 [ppm/K], 13 [ppm/K], and 14 [ppm/K]. Of AlSi, Ni, and Au, which constitute the metal electrode 20, a linear expansion coefficient of AlSi is about 20 [ppm/K]. Thus, an effective linear expansion coefficient of the back surface electrode 14 by the four layers of the metal films, which constitute the back surface electrode 14, (that is, a substantial linear expansion coefficient when the back surface electrode 14 is regarded as a single member) is larger than the linear expansion coefficient of the semiconductor substrate 12. In addition, an effective linear expansion coefficient of the metal electrode 20 by each of the metal films, which constitute the metal electrode 20, (that is, an effective linear expansion coefficient when the metal electrode 20 is regarded as a single member) is also larger than the linear expansion coefficient of the semiconductor substrate 12.

Next, a specific description will be made on a relationship between the thickness t1 of the back surface electrode 14 and the thickness t2 of the metal electrode 20. In general, in solder joining by the reflow soldering method, solder is melted at 200 to 300[° C.]. In the reflow soldering method, when the semiconductor chip 24 is heated to a solder melting temperature, the semiconductor substrate 12, the back surface electrode 14, and the metal electrode 20 each intend to expand thermally. Since the back surface electrode 14 has the larger linear expansion coefficient than the semiconductor substrate 12, the back surface electrode 14 intends to expand thermally in a manner to become larger than the semiconductor substrate 12. However, the back surface electrode 14 is restrained by the back surface 12a of the semiconductor substrate 12. Thus, when the back surface electrode 14 expands thermally, the back surface electrode 14 applies a tensile force in a surface direction to the back surface 12a of the semiconductor substrate 12. This tensile force includes a volume of the back surface electrode 14, the effective linear expansion coefficient, and a temperature change as factors. Similarly, since the metal electrode 20 has the larger linear expansion coefficient than the semiconductor substrate 12, the metal electrode 20 intends to expand thermally in a manner to become larger than the semiconductor substrate 12. However, the metal electrode 20 is restrained by the front surface 12b of the semiconductor substrate 12. Thus, when the metal electrode 20 expands thermally, the metal electrode 20 applies a tensile force in a surface direction to the front surface 12b of the semiconductor substrate 12. This tensile force includes a volume of the metal electrode 20, the effective linear expansion coefficient, and a temperature change as factors. In this embodiment, the thickness t1 of the back surface electrode 14 is set to be larger than the thickness t2 of the metal electrode 20, surface areas of the back surface electrode 14 and the metal electrode 20 are adjusted (that is, the volume of the back surface electrode 14 is set to be larger than the volume of the metal electrode 20), and the effective linear expansion coefficient and a longitudinal elastic modulus of each of the electrodes 14, 20 are adjusted. Accordingly, the tensile force that is applied to the back surface 12a of the semiconductor substrate 12 from the back surface electrode 14 is set to be larger than the tensile force applied to the front surface 12b of the semiconductor substrate 12 from the metal electrode 20 at the solder melting temperature.

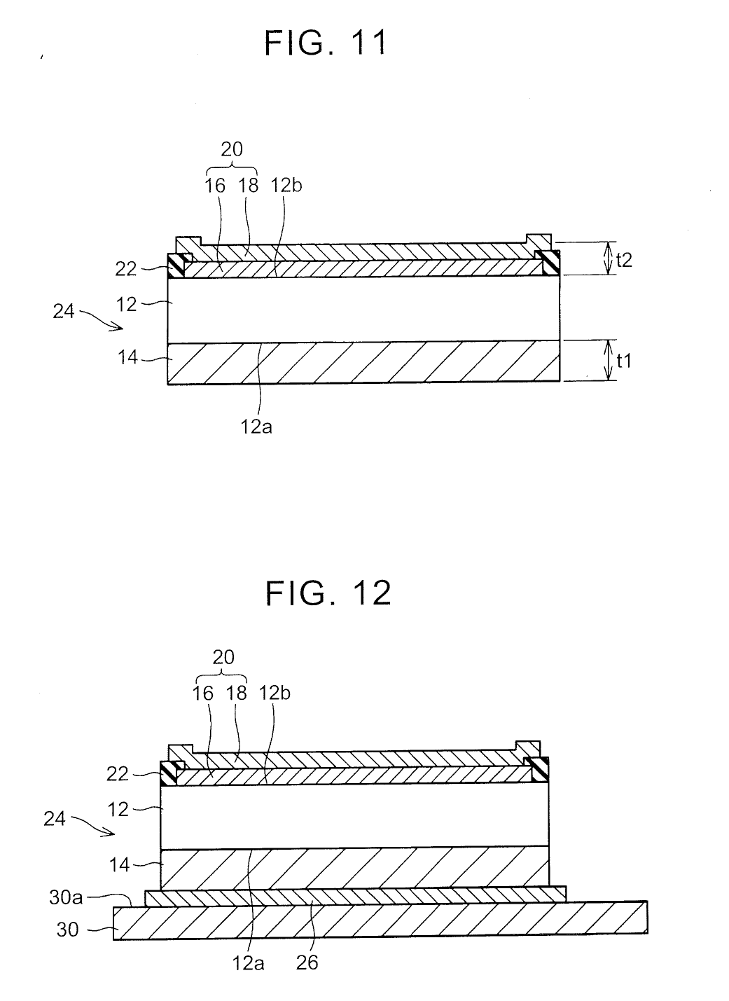

(Method of Manufacturing Semiconductor Device) Next, a description will be made on a method of manufacturing the semiconductor device 10 with reference to FIG. 11 to FIG. 15. In the method of manufacturing the semiconductor device 10, a semiconductor substrate preparing process, an electrode forming process, an introducing process, a furnace heating process, a cooling process, an upper lead frame joining process, and a resin layer forming process are carried out to manufacture the semiconductor device 10.

(Semiconductor Substrate Preparing Process and Electrode Forming Process) First, as shown in FIG. 11, the semiconductor substrate 12 is prepared. The semiconductor substrate 12 is formed with the semiconductor element structure. Since a method of forming the semiconductor element structure is a conventionally known method, a description thereof will not be made. Next, the back surface electrode 14 is formed on the back surface 12a of the semiconductor substrate 12, and the front surface electrode 16 is formed on the front surface 12b by a sputtering method or the like. Then, the outer periphery of the front surface electrode 16 is etched, and the insulation layer 22 is formed on the front surface 12b of the semiconductor substrate 12 and on the front surface of the front surface electrode 16 by a known method. Next, the insulation layer 22 is etched except for an outer periphery thereof, so as to expose the front surface electrode 16. The front surface electrode 18 is formed on the front surface of the front surface electrode 16 by using a mask sputtering method. The metal electrode 20 is formed of the front surface electrode 16 and the front surface electrode 18. Accordingly, the semiconductor chip 24 is formed. The thickness t1 of the back surface electrode 14 is set to be larger than the thickness t2 of the metal electrode 20. More specifically, values of t1 and t2 are set such that the tensile force that is applied to the semiconductor substrate back surface 12a when the semiconductor chip 24 is heated to the melting temperature of the solder 26 and the back surface electrode 14 expands thermally is larger than the tensile force that is applied to the semiconductor substrate front surface 12b when the metal electrode 20 expands thermally. Here, a ratio of t1 to t2 is determined in consideration of a kind and a thickness of a material that constitutes each of the electrodes 14, 20. In the method of manufacturing the semiconductor device 10, the front surface electrode 18 is formed by the mask sputtering method. However, a method of manufacturing the front surface electrode 18 is not limited thereto. For example, the front surface electrode may be formed by using a non-electrolytic plating method.

(Introducing Process) Next, as shown in FIG. 12, a solder foil (hereinafter referred to as the solder 26) is placed on the front surface 30a of the lead frame 30, and the semiconductor chip 24 is arranged such that the back surface electrode 14 of the semiconductor chip 24 contacts a front surface of the solder foil. In other words, the back surface electrode 14 faces the front surface 30a of the lead frame 30 via the solder 26. The lead frame 30, on which the semiconductor chip 24 is arranged, is introduced into a reflow furnace. At this time, a temperature inside the reflow furnace is a room temperature.

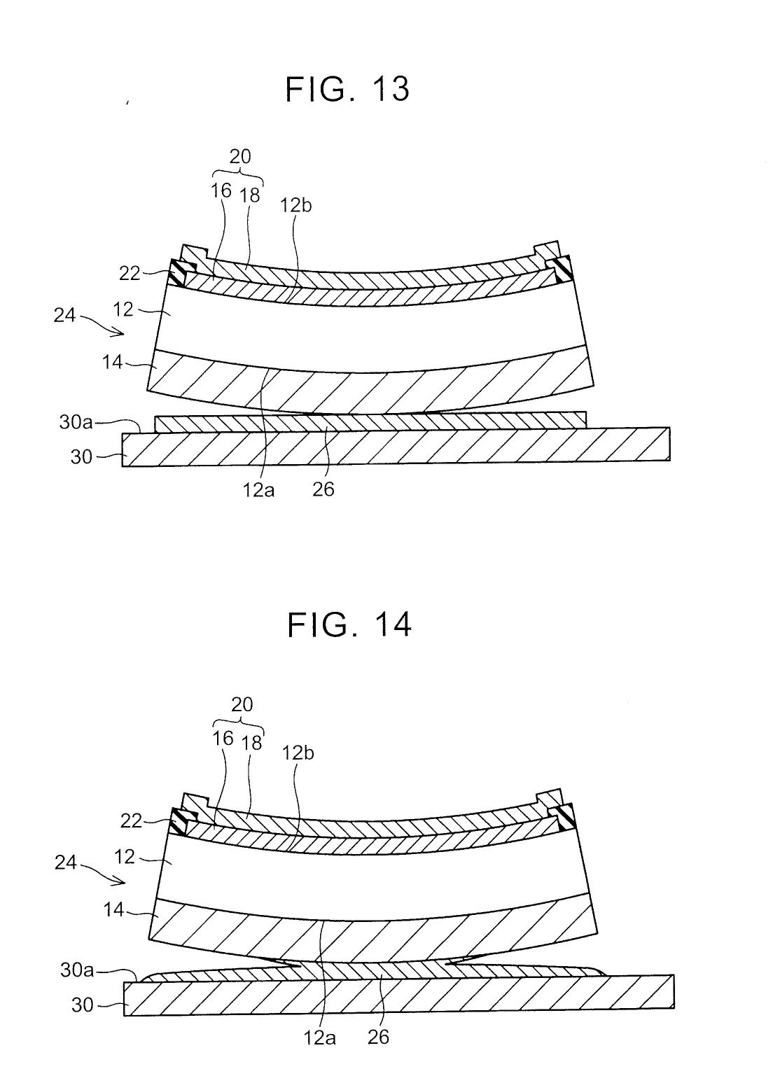

(Furnace Heating Process) Next, the reflow furnace into which the lead frame 30, on which the semiconductor chip 24 is arranged, is introduced is gradually heated to the melting temperature of the solder 26. As the reflow furnace is heated, the semiconductor substrate 12, the back surface electrode 14, and the metal electrode 20 expand thermally. Due to the differences in the linear expansion coefficient among the semiconductor substrate 12, the back surface electrode 14, and the metal electrode 20, the tensile force is applied to each of the back surface 12a and the front surface 12b of the semiconductor substrate 12. The thickness t1 of the back surface electrode 14 and the thickness t2 of the metal electrode 20 are set such that the tensile force applied to the semiconductor substrate back surface 12a is larger than the tensile force applied to the semiconductor substrate front surface 12b at the solder melting temperature. Thus, as shown in FIG. 13, as the reflow furnace is heated, the semiconductor chip 24 is warped to project with respect to the lead frame 30, and a projected portion of the semiconductor chip 24 is brought into contact with the solder 26. Once the inside of the furnace is heated to the melting temperature of the solder 26, the solder 26 starts being melted as shown in FIG. 14 and spreads from a contact portion with the semiconductor chip 24.

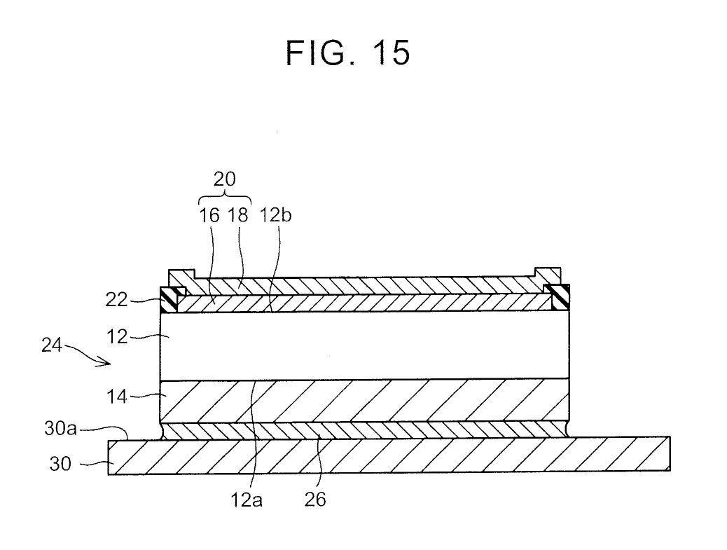

(Cooling Process) Next, the reflow furnace is gradually cooled to the room temperature. When the reflow furnace is cooled, as shown in FIG. 15, the semiconductor chip 24 returns to a shape thereof at the room temperature, and the solder 26 hardens. Accordingly, the front surface 30a of the lead frame 30 is joined to the back surface electrode 14 of the semiconductor chip 24 by soldering.

(Upper Lead Frame Joining Process) Next, the lead frame 32 (that is, the upper lead frame) is joined to the metal electrode 20 by soldering. Since a method is the same as the method of joining the lead frame 30 to the back surface electrode 14 by soldering, a description thereof will not be made.

(Resin Layer Forming Process) Next, the thermosetting resin is injection molded, and the semiconductor chip 24 is sealed by the resin. Since a method of injection molding is conventionally known, a description thereof will not be made. Although the epoxy resin is used as the thermosetting resin, for example, the thermosetting resin is not limited thereto. A resin layer that is formed by the injection molding is formed to cover an entire exposed surface of the semiconductor chip 24, part of the lead frame 30, and part of the lead frame 32. Then, the resin layer that is formed on an opposite surface of each of the lead frames 30, 32 from a surface thereof that contacts the semiconductor chip 24 is removed by a CMP method or the like. Here, a polishing method is not limited to the CMP method.

The semiconductor device 10, which is shown in FIG. 1, is manufactured by the above-described method of manufacturing.

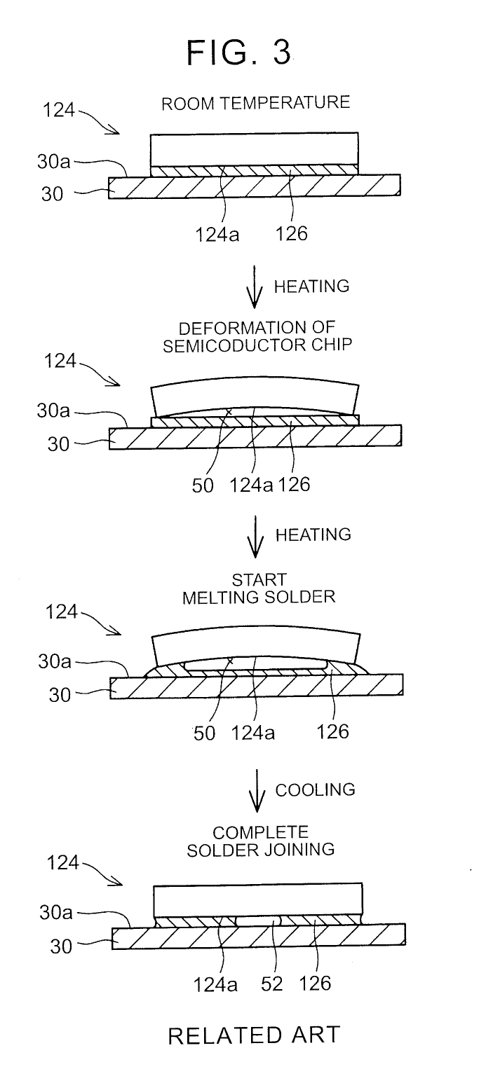

A description will be made on effects of the semiconductor device 10 of this embodiment while a comparison with a semiconductor chip 124 (a comparative example 1) of the related art is made. FIG. 2 is a vertical cross-sectional view of the semiconductor chip 124 of the related art. While the semiconductor chip 124 is formed of the same materials as the semiconductor chip 24 of this embodiment, it differs from the semiconductor chip 24 of this embodiment in a point that a thickness t4 of a metal electrode 120 is larger than a thickness t3 of a back surface electrode 114. FIG. 3 shows a procedure of joining the lead frame 30 by soldering to the back surface electrode 114 of the semiconductor chip 124 of the related art by the reflow soldering method. First, solder 126 is printed on the front surface 30a of the lead frame 30 at the room temperature, and the semiconductor chip 124 is placed on the lead frame 30. Then, the lead frame 30, on which the semiconductor chip 124 is placed, is introduced into the reflow furnace, and the inside of the reflow furnace is gradually heated. As described above, t3<t4 is satisfied in the comparative example 1. Thus, depending on values of the effective linear expansion coefficients of the back surface electrode 114 and the metal electrode 120, a tensile force that is applied to the back surface 12a of the semiconductor substrate 12 from the back surface electrode 114 in a heating procedure is smaller than a tensile force that is applied to the front surface 12b of the semiconductor substrate 12 from the metal electrode 120. Accordingly, the front surface of the semiconductor substrate 12 on the metal electrode 120 side expands thermally in a manner to become larger than the front surface thereof on the back surface electrode 114 side. Thus, the semiconductor chip 124 is warped to be recessed with respect to the lead frame 30. Then, a gap 50 is formed between a semiconductor chip back surface 124a and a front surface of the solder 126, and only an outer peripheral portion of the semiconductor chip back surface 124a is brought into contact with the solder 126. As apparent from FIG. 3, the gap 50 is a closed space.

When the inside of the furnace is further heated and reaches a melting temperature of the solder 126, the solder 126 spreads wetly from a contact portion with the semiconductor chip back surface 124a and is joined from the contact portion. At this time, the gap 50 is surrounded by the outer peripheral portion of the semiconductor chip back surface 124a. Thus, the air in the gap 50 is less likely to move to the outside, is incorporated into the solder 126 in the procedure of solder joining, and turns into a bubble 52. As a result, even when the semiconductor chip 124 is cooled and a shape thereof returns to the shape before heating, the bubble 52 remains in the solder.

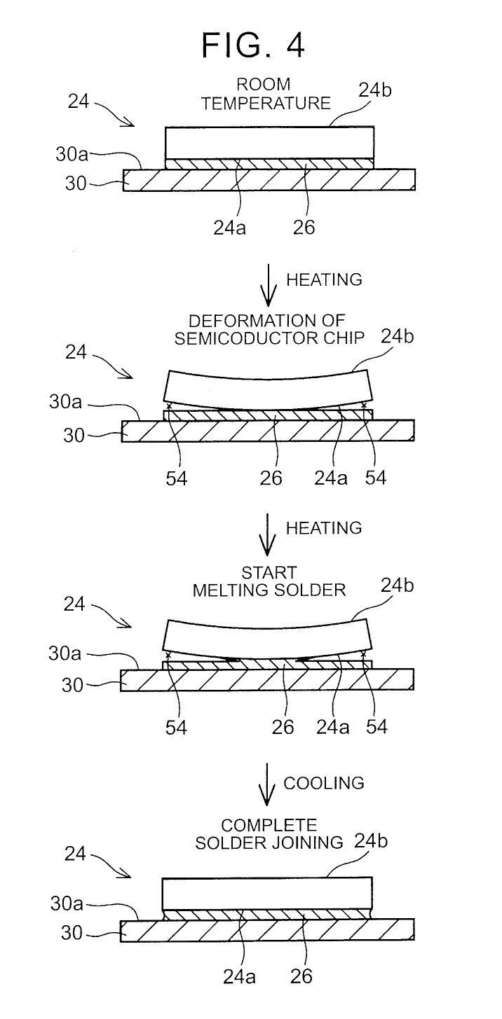

FIG. 4 schematically shows a procedure of joining the lead frame 30 by soldering to the back surface electrode 14 of the semiconductor chip 24 of this embodiment by the reflow soldering method. As it has already been described above, the semiconductor chip 24 is placed on the lead frame 30 via the solder 26 by the same method as the conventional method. Next, the lead frame 30, on which the semiconductor chip 24 is placed, is introduced into the reflow furnace, and the inside of the furnace is gradually heated. As described above, when the semiconductor chip 24 of this embodiment is heated, the tensile force that is applied to the back surface 12a of the semiconductor substrate 12 from the back surface electrode 14 becomes larger than the tensile force that is applied to the front surface 12b of the semiconductor substrate 12 from the metal electrode 20. Accordingly, the semiconductor chip 24 is warped to project with respect to the lead frame 30. Thus, a center portion of the back surface 24a of the semiconductor chip 24 (that is, a portion that is projected with respect to the lead frame 30) is brought into contact with the solder 26. At this time, a gap 54 is formed between the semiconductor chip back surface 24a and the front surface of the solder 26. As apparent from FIG. 4, the gap 54 is a space that is opened to the outside.

When the inside of the furnace is further heated and reaches the melting temperature of the solder 26, the solder 26 spreads wetly from a contact portion with the semiconductor chip back surface 24a and is radially joined from the center portion of the back surface 24a. At this time, since the gap 54 is the space that is opened to the outside, the air in the gap 54 is pushed out to the outside in a procedure in which the solder 26 spreads radially. Accordingly, the air is less likely to be incorporated into the solder 26, and it is thus possible to suppress formation of the bubble in the solder 26 at the time of completion of solder joining. Therefore, it is possible to suppress reduction in thermal conductivity and reduction in electric conductivity of the semiconductor device 10 that are caused by the formation of the bubble in the solder.

A phenomenon that the semiconductor chip 124 is warped to be recessed with respect to the lead frame 30 at the solder melting temperature is particularly commonly seen in a semiconductor device of double-sided joint type. More specifically, in the semiconductor device of double-sided joint type, the front surface electrode that is constituted by the Ni layer and the Au layer is formed on the front surface electrode in order to appropriately join the lead frame and the like onto the front surface electrode of the semiconductor chip by soldering. There is a case where part of the Ni layer is lost by solder joining and where solder joining strength is deteriorated. Thus, the Ni layer is generally formed to be thick to a certain degree. Accordingly, in the semiconductor device of double-sided joint type, like the semiconductor chip 124, the total thickness t4 of the front surface electrode 116 and the front surface electrode 118 tends to be larger than the thickness t3 of the back surface electrode 114. In such a semiconductor device, as described above, when the lead frame is joined to the back surface electrode of the semiconductor chip by soldering, there is a case where the bubble is mixed in the solder. This problem is new knowledge that is obtained by the inventor as a result of the earnest study. The present invention is thus provided to solve the problem that is based on this knowledge. Thus, it is possible by using the present invention to manufacture a semiconductor device in which the bubble is unlikely to be formed in a solder even when the semiconductor device is the semiconductor device of double-sided joint type. Here, the present invention is not limited to the semiconductor device of double-sided joint type. For example, the present invention can be used for a semiconductor device in which only one surface of the semiconductor chip is joined to the lead frame and the like. In addition, the back surface electrode and/or the metal electrode may be formed of one kind of material.

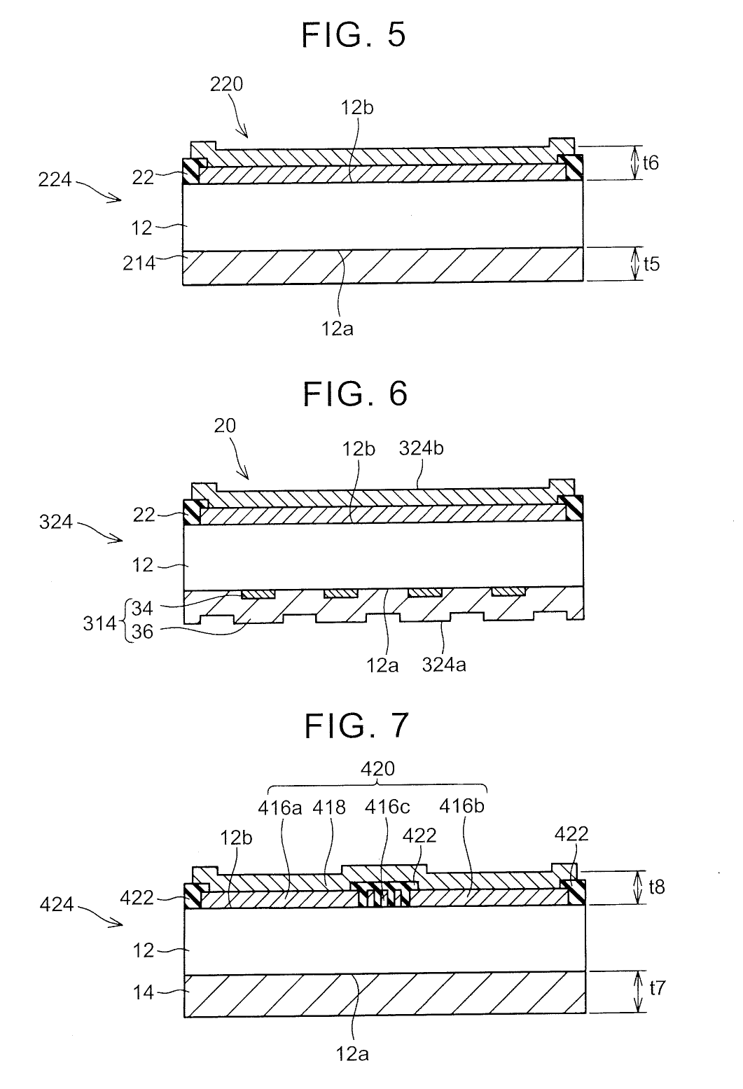

Next, a description will be made on a second embodiment with reference to FIG. 5. A description will hereinafter be made only on points that differ from the first embodiment, and a detailed description on the same configuration as that of the first embodiment will not be made.

While a semiconductor chip 224 of the second embodiment is formed of the same materials as those of the semiconductor chip 24 of the first embodiment, it differs from the semiconductor chip 24 in a point that a thickness t5 of a back surface electrode 214 is substantially the same as a thickness t6 of a metal electrode 220. In addition, in this embodiment, a thickness of each of metal films that constitute the back surface electrode 214 and the metal electrode 220 is adjusted such that an effective linear expansion coefficient of the back surface electrode 214 is larger than an effective linear expansion coefficient of the metal electrode 220.

Here, the back surface electrode 214 and the metal electrode 220 have the substantially same volume. Thus, according to this configuration, as the semiconductor chip 224 is heated by using the reflow soldering method, the back surface electrode 214, whose effective linear expansion coefficient is larger than the metal electrode 220, intends to expand thermally in a manner to become larger than the metal electrode 220. Accordingly, a tensile force that is applied to the back surface 12a of the semiconductor substrate 12 from the back surface electrode 214 due to thermal expansion of the back surface electrode 214 is larger than a tensile force that is applied to the front surface 12b of the semiconductor substrate 12 from the metal electrode 220 due to thermal expansion of the metal electrode 220. Consequently, the semiconductor chip 224 is warped to project with respect to the lead frame 30. Therefore, a semiconductor device that includes the semiconductor chip 224 of the second embodiment has the same effects as the semiconductor device 10 of the first embodiment. In this embodiment, the thickness t5 of the back surface electrode 214 is substantially the same as the thickness t6 of the metal electrode 220. However, in a case where a difference in the effective linear expansion coefficient of the back surface electrode 214 with respect to the metal electrode 220 is increased and where the tensile force that is applied to the back surface 12a of the semiconductor substrate 12 thus becomes larger than the tensile force that is applied to the front surface 12b, the thickness t5 of the back surface electrode 214 may be smaller than the thickness t6 of the metal electrode 220.

In other words, in the first embodiment, the volume of the back surface electrode 14 is set to be larger than the volume of the metal electrode 20, and the tensile force that is generated by the back surface electrode 14 is thereby set to be larger than the tensile force that is generated by the metal electrode 20. Meanwhile, in this embodiment, the effective linear expansion coefficient of the back surface electrode 214 is set to be larger than the effective linear expansion coefficient of the metal electrode 220, and the tensile force that is generated by the back surface electrode 214 is thereby set to be larger than the tensile force that is generated by the metal electrode 220.

Next, a description will be made on a third embodiment with reference to FIG. 6. A description will hereinafter be made only on points that differ from the first embodiment, and a detailed description on the same configuration as that of the first embodiment will not be made.

In a semiconductor chip 324 of the third embodiment, a back surface electrode 314 is formed on the back surface 12a of the semiconductor substrate 12. The back surface electrode 314 is constituted by plural metal films 34 and a metal film 36. The plural metal films 34 are each made of Al, and are formed in stripes on the back surface 12a of the semiconductor substrate 12. The plural metal films 34 are arranged at specified intervals in a lateral direction of the sheet, and each thereof extends in a direction toward the back of the sheet. The metal film 36 is formed of four layers of the metal films, and is constituted by the Al film, the Ti film, the Ni film, and the Au film in this order from above. The metal film 36 is formed as a continuous film that covers the back surface 12a of the semiconductor substrate 12, lateral surfaces and a back surface of the each metal film 34. Thus, steps in the stripes are formed on a back surface of the metal film 36 (that is, a back surface 324a of the semiconductor chip 324). As a result, a surface area of the back surface 324a of the semiconductor chip 324 becomes larger than a surface area of a front surface 324b of the semiconductor chip 324. In general, a degree of expansion of a material is increased as a surface area of the material is increased. In this embodiment, since the back surface 324a of the back surface electrode 314 is formed with the steps, the surface area of the back surface 324a becomes larger than the surface area of the front surface 324b of the metal electrode 20. Accordingly, a degree of expansion of the back surface 324a of the back surface electrode 314 becomes larger than a degree of expansion of the front surface 324b of the metal electrode 20. In other words, a degree of expansion of the back surface electrode 314 in the surface direction is larger than a degree of expansion of the metal electrode 20 in the surface direction. Accordingly, a tensile force that is generated by the back surface electrode 314 is set to be larger than a tensile force that is generated by the metal electrode 20. Therefore, the same effects as those obtained by the semiconductor device 10 of the first embodiment can be obtained by this configuration.

In other words, the materials for the metal films are appropriately selected in the second embodiment, thereby adjusting the magnitude relationship in the effective linear expansion coefficient among the electrodes on both sides. Meanwhile, in the third embodiment, a shape of the each layer is changed to increase the surface area, so as to change a magnitude relationship in the degree of expansion among the electrodes on both sides.

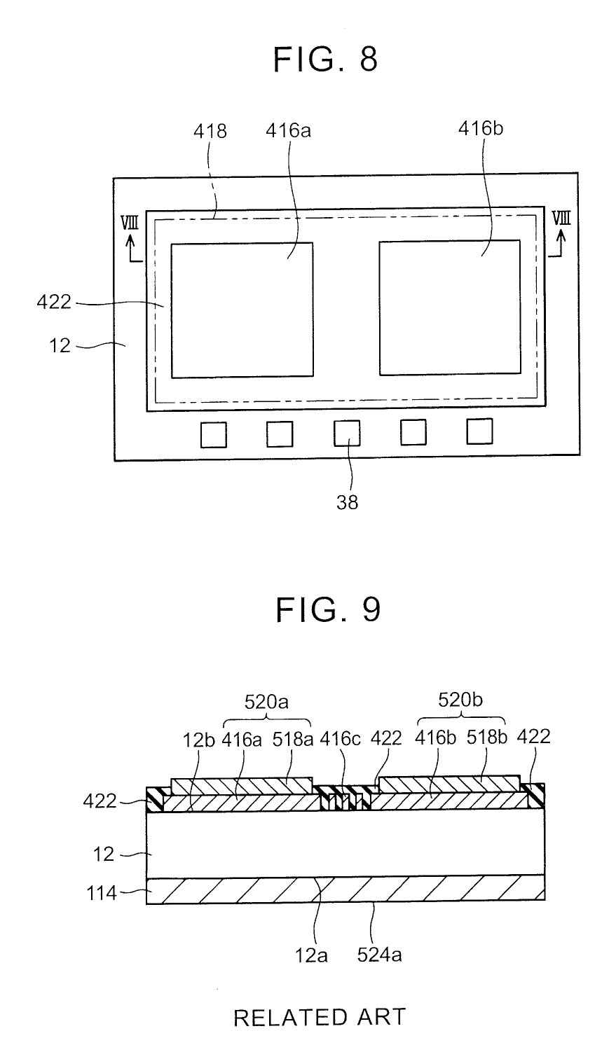

Next, a description will be made on a fourth embodiment with reference to FIGS. 7, 8. A description will hereinafter be made only on points that differ from the first embodiment, and a detailed description on the same configuration as that of the first embodiment will not be made.

FIG. 7 is a vertical cross-sectional view of a semiconductor chip 424 of the fourth embodiment, and FIG. 8 is a plan view of the semiconductor chip 424. FIG. 7 corresponds to the vertical cross-sectional view that is taken along the VIII-VIII line of the semiconductor chip 424 in FIG. 8. More strictly, FIG. 7 is a vertical cross-sectional view of a rectangular insulation layer 422 (which will be described below) from a left end to a right end thereof in the plan view that is shown in FIG. 8. In FIG. 8, a front surface electrode 418 (which will be described below) is indicated by a two-dot chain line, and a front surface electrode 416c is not shown for easy recognition of the drawing. As shown in FIGS. 7, 8, this embodiment differs from the first to third embodiments in a point that plural front surface electrodes 416 (416a to 416c) are funned (separately) at specified intervals on the front surface 12b of the semiconductor substrate 12. The front surface electrode 416a and the front surface electrode 416b are each formed in a rectangular shape in the plan view and in substantially the same size. The front surface electrode 416a and the front surface electrode 416b are formed on the front surface 12b of the semiconductor substrate 12 with a gap being interposed therebetween, and the three front surface electrodes 416c, each of which functions as a wiring layer is formed between the front surface electrode 416a and the front surface electrode 416b. In the front surface electrodes 416a to 416c, adjacent end surfaces are parallel to each other. AlSi is used for the front surface electrodes 416.

The insulation layer 422 is formed on an outer periphery of each of the front surface electrodes 416a, 416b and the gap between the adjacent front surface electrodes 416. More specifically, the insulation layer 422 is formed to cover end surfaces of the front surface electrodes 416a, 416b and part of each of front surfaces of the front surface electrodes 416a, 416b in the outer peripheries thereof, and also to cover end surfaces and an entire front surface of the front surface electrode 416c. As shown in FIG. 8, a contour of the insulation layer 422 is rectangular, and the insulation layer 422 is formed such that the front surfaces of the front surface electrodes 416a, 416b except the outer peripheries are exposed. Polyimide is used for the insulation layer 422.

The front surface electrode 418 is formed on exposed surfaces of the front surface electrodes 416a, 416b and the front surface of the insulation layer 422 except the outer periphery thereof (that is, a range indicated by the two-dot chain line in FIG. 8). The front surface electrode 418 is formed of a continuous and seamless metal film, and is formed across the front surface electrodes 416 and the insulation layer 422. The front surface electrode 418 is formed by the mask sputtering method, and a detailed description thereof will be made below. The front surface electrode 418 is formed by the Ni film and the Au film in this order from below. A metal electrode 420 is constituted by the front surface electrode 416 and the front surface electrode 418. Here, a magnitude relationship in linear expansion coefficients among the materials that constitute the front surface electrodes 416, the insulation layer 422, and the front surface electrode 418 will be described. A linear expansion coefficient of polyimide is about 40 [ppm/K]. Thus, the linear expansion coefficients of the materials (Ni, Au) that constitute the front surface electrode 418 are set to be smaller than the linear expansion coefficient of the material (AlSi) that constitutes the front surface electrodes 416 and the linear expansion coefficient of the material (polyimide) that constitutes the insulation layer 422. In addition, in this embodiment, a thickness t7 of the back surface electrode 14 is set to be larger than a thickness t8 of the metal electrode 420, so that a tensile force that is applied to the back surface 12a of the semiconductor substrate 12 from the back surface electrode 14 at the solder melting temperature is set to be larger than a tensile force that is applied to the front surface 12b of the semiconductor substrate 12 from the metal electrode 420. Furthermore, as shown in FIG. 8, a gate pad 38 is formed on the front surface 12b of the semiconductor substrate 12. Since the gate pad 38 is a member that has a conventionally known function, a description thereof will not be made. Here, the front surface electrodes 416 (416a, 416b, 416c) may be regarded as the “first layer”. The front surface electrode 418 may be regarded as the “second layer”.

A description will be made on effects of the semiconductor device of this embodiment with reference to a semiconductor chip 524 (a comparative example 2) of the related art. FIG. 9 is a vertical cross-sectional view of the semiconductor chip 524 of the related art. While the semiconductor chip 524 is formed of the same materials as those used for the semiconductor chip 424 of this embodiment, it differs from the semiconductor chip 424 of this embodiment in a point that front surface electrodes 518 (518a, 518b) are formed by the non-electrolytic plating method. In the non-electrolytic plating method, the front surface electrodes 518 are formed only on the exposed surfaces of the front surface electrodes 416a, 416b. Thus, a metal electrode 520a that is constituted by the front surface electrode 416a and the front surface electrode 518a and a metal electrode 520b that is constituted by the front surface electrode 416b and the front surface electrode 518b are formed on the front surface 12b of the semiconductor substrate 12 with a gap being interposed therebetween. Here, the linear expansion coefficient of the insulation layer 422 is larger than an effective linear expansion coefficient of a metal electrode 520. Thus, members with the different linear expansion coefficients are arranged on different portions of the front surface 12b of the semiconductor substrate 12.

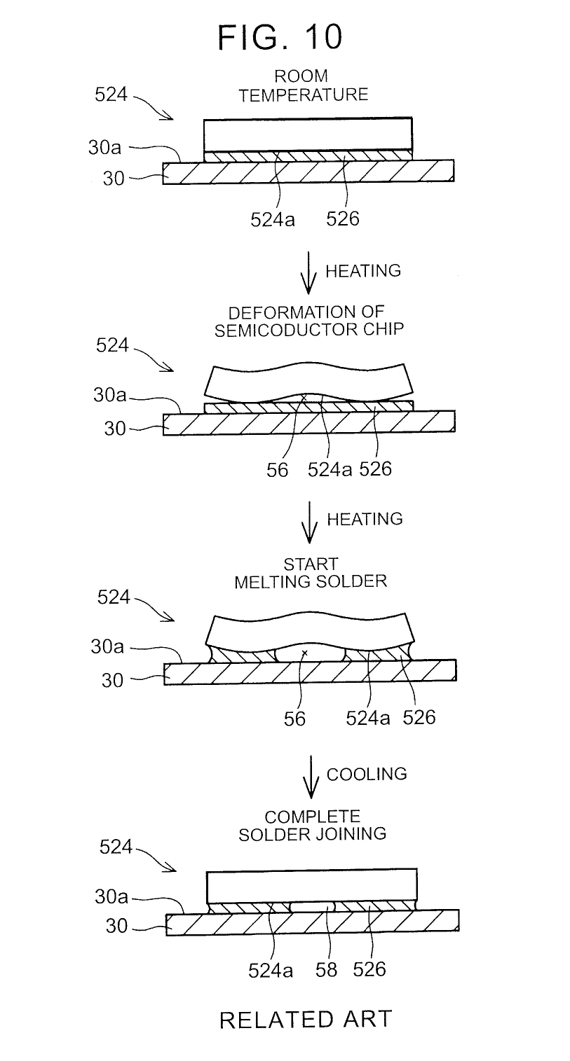

FIG. 10 shows a procedure of joining the lead frame 30 by soldering to the back surface electrode 114 of the semiconductor chip 524 of the related art by the reflow soldering method. First, in the same procedure as that in FIG. 3, the semiconductor chip 524 is placed on the front surface 30a of the lead frame 30 via solder 526. Next, the lead frame 30, on which the semiconductor chip 524 is placed, is introduced into the reflow furnace, and the inside of the furnace is gradually heated. Here, the insulation layer 422 intends to expand thermally in a manner to become larger than the metal electrode 520. In addition, the linear expansion coefficient of the insulation layer 422 is larger than that of the back surface electrode 114. As a result, depending on a magnitude relationship in thickness between the back surface electrode 114 and the insulation layer 422 and on longitudinal elastic moduli of the back surface electrode 114 and the insulation layer 422, the semiconductor chip 524 may be warped in a waveform (that is, warped to be locally recessed with respect to the lead frame 30). When the semiconductor chip 524 is warped in the waveform, a gap 56 is formed between a semiconductor chip back surface 524a and a front surface of the solder 526, and a portion of the semiconductor chip 524 that is projected with respect to the lead frame 30 is brought into contact with the solder 526. Also in this case, like the semiconductor chip 124 in FIG. 3, when the inside of the furnace is further heated and reaches a melting temperature of the solder 526, the solder 526 spreads from a contact portion with the semiconductor chip back surface 524a and is joined from the contact portion. At this time, since the gap 56 is surrounded by the contact portion, the air in the gap 56 is less likely to move to the outside, is incorporated into the solder 526 in the procedure of solder joining, and turns into a bubble 58. As a result, even when the semiconductor chip 524 is cooled and a shape thereof returns to the shape before heating, the bubble 58 remains in the solder.

Meanwhile, in this embodiment, the front surface electrode 418 that has the smaller linear expansion coefficient than the front surface electrodes 416 and the insulation layer 422 is formed as the continuous and seamless metal film on the exposed surfaces of the front surface electrodes 416a, 416b and the front surface of the insulation layer 422 except the outer periphery thereof. The degree of thermal expansion of the front surface electrode 418 that covers the front surfaces of the front surface electrodes 416 and the insulation layer 422 is smaller than the degrees of thermal expansion of the front surface electrodes 416 and the insulation layer 422. Thus, in the heating procedure of the reflow soldering method, even when the front surface electrodes 416 and the insulation layer 422 expand thermally at the different linear expansion coefficients from each other, the front surface electrode 418 suppresses the thermal expansion of the front surface electrode 416 and the insulation layer 422 at the different linear expansion coefficients. In other words, a difference in the linear expansion coefficient between the front surface electrode 416 and the insulation layer 422 is alleviated by the front surface electrode 418 that covers the front surfaces of the front surface electrode 416 and the insulation layer 422. Thus, the application of the tensile force that differs by the portions of the semiconductor substrate front surface 12b is suppressed. Therefore, the semiconductor chip 424 is suppressed from being warped in a manner to locally project with respect to the lead frame 30. In addition, t7>t8 is satisfied in the semiconductor chip 424 of this embodiment. Thus, the tensile force that is applied to the back surface 12a of the semiconductor substrate 12 by the back surface electrode 14 at the solder melting temperature is set to be larger than the tensile force that is applied to the front surface 12b of the semiconductor substrate 12 by the metal electrode 420. Accordingly, when the semiconductor chip 424 is heated, it is warped to project with respect to the lead frame 30. Therefore, when the lead frame 30 is joined to the back surface electrode 14 of the semiconductor chip 424 by using the reflow soldering method, it is possible to suppress the formation of the bubble in the solder. Here, in this embodiment, the tensile force that is generated by the back surface electrode 14 is set to be larger than the tensile force that is generated by the metal electrode 420 by adjusting the magnitude relationship in thickness between the back surface electrode 14 and the metal electrode 420. However, the present invention is not limited thereto. For example, the tensile force that is generated by the back surface electrode 14 may be set larger than the tensile force that is generated by the metal electrode 420 by adjusting the magnitude relationship in the effective linear expansion coefficient between the back surface electrode 14 and the metal electrode 420.

The semiconductor device that includes the semiconductor chip 424 of the fourth embodiment can be manufactured in substantially the same manufacturing method of the above-described semiconductor device 10. However, the manufacturing method differs from that of the semiconductor device 10 in the following points. More specifically, in the semiconductor device that includes the semiconductor chip 424, the front surface electrode 418 is manufactured by the mask sputtering method. In other words, the non-electrolytic plating method is not used. It is possible by using the mask sputtering method to form the front surface electrode 418 as the continuous and seamless metal film not only on the exposed surfaces of the front surface electrodes 416a, 416b but also the front surface of the insulation layer 422. In addition, the materials that are used to constitute the front surface electrode 418 have smaller linear expansion coefficients than the materials that constitute the front surface electrode 416 and the insulation layer 422. Here, any method other than the mask sputtering method may be used unless the method can form the front surface electrode 418 as the continuous and seamless metal film on the exposed surfaces of the front surface electrodes 416a, 416b and the front surface of the insulation layer 422 except the outer periphery.

The embodiments of the present invention have been described in detail so far, they are merely illustrative. The semiconductor device and the method of manufacturing the semiconductor device of the present invention include various changes and modifications of the above-described embodiments.

For example, in the above-described embodiments, the shape of the semiconductor chip in the room temperature and after completion of joining of the lead frame 30 is illustrated to be flat. However, the semiconductor chip in the room temperature and after the completion of joining of the lead frame 30 may have any shape as long as the semiconductor chip is configured to be warped to project with respect to the lead frame 30 at the solder melting temperature. That is, the semiconductor chip may be recessed or may be projected with respect to the lead frame 30.

In the upper lead frame joining process, it is considered that the semiconductor chip is warped to be recessed with respect to the lead frame 32 (that is, the upper lead frame) at the solder melting temperature. However, when the upper lead frame is joined to the front surface of the semiconductor chip, the lower lead frame is joined to the back surface of the semiconductor chip, and the tensile forces that apply to the front surface and the back surface of the semiconductor chip vary. Thus, also in the upper lead frame joining process, it is estimated that the semiconductor chip is warped to project with respect to the lead frame 32 (that is, the upper lead frame). As an experiment, the semiconductor device was manufactured by applying the embodiment of the present invention. When the lead frame 32 was joined to the metal electrode of the semiconductor chip, a problem that bubbles were formed in the solder did not occur. In addition, when the lead frame 30 was joined to the back surface electrode, the problem of bubble formation in the solder was significantly improved. Accordingly, it was confirmed that the present invention was useful for the semiconductor device of double-sided joint type.

In the above-described embodiments, the process of joining the lower lead frame and the process of joining the upper lead frame are carried out separately. However, the upper and lower lead frames may simultaneously be joined to the semiconductor chip. More specifically, a solder foil is placed on the front surface of the lower lead frame, and the semiconductor chip is arranged on the front surface thereof. Then, the solder foil (the same material as the solder foil placed on the front surface of the lower lead frame) is placed on the front surface of the semiconductor chip, and the upper lead frame is arranged on the front surface thereof. The component just as described is introduced into the reflow furnace, and heated to melt the solder foil. Then, the component is cooled to harden the solder. This causes the upper and lower lead frames to be simultaneously joined to the semiconductor chip. Also in this case, the problem of bubble formation in the solder for joining the lower lead frame was significantly improved. In addition, the problem of bubble formation in the solder for joining the upper lead frame did not occur. Compared to a method of manufacturing in which the upper lead frame and the lower lead frame are separately joined, according to this method, the number of processes can be reduced, and cost can also be reduced. Here, a metal block may be arranged between the front surface of the semiconductor chip and the upper lead frame.

In the above-described embodiments, the linear expansion coefficients of the each material in two directions that are orthogonal to the front surface of the semiconductor substrate are substantially the same. Thus, when the semiconductor chip is heated, the each material expands thermally at substantially the same ratio in a front surface direction of the semiconductor substrate. In addition, since the linear expansion coefficient is generally a temperature-dependent coefficient, a value of the linear expansion coefficient varies in a procedure of heating the semiconductor chip from the room temperature to the solder melting temperature. Thus, it is preferred to set the values of the effective linear expansion coefficients of the back surface electrode and the metal electrode such that the tensile force that is applied to the back surface of the semiconductor substrate is larger than the tensile force that is applied to the front surface of the semiconductor substrate at the solder melting temperature.

The above-described embodiments illustrate the case where the magnitude relationship of the tensile forces that are applied to the semiconductor substrate by the back surface electrode and the metal electrode is established. However, the embodiment of the present invention is not limited to the above-described embodiments. The tensile forces that are applied to the semiconductor substrate by the back surface electrode and the metal electrode may substantially the same. In this case, the thickness of the back surface electrode and that of the metal electrode may substantially be the same, the effective linear expansion coefficient of the back surface electrode and that of the metal electrode may substantially be the same, and the front surface area of the back surface electrode and that of the metal electrode may substantially be the same. Alternatively, combination of the above may be adopted.

In the above-described embodiment, the IGBT is raised as the semiconductor chip. However, the semiconductor chip is not limited thereto. Any of various semiconductor elements such as a MOSFET may be used. In addition, the semiconductor substrate is not limited to the Si substrate, and the SiC substrate may be used, for example. Furthermore, materials that constitute the back surface electrode, the each front surface electrode (metal electrode), and the insulation layer are not limited to the materials raised in the above-described embodiments as long as the tensile force that is applied to the back surface of the semiconductor substrate is configured to be larger than the tensile force that is applied to the front surface of the semiconductor substrate at the solder melting temperature. In addition, in the furnace temperature increasing process, the reflow furnace may be heated to a higher temperature than the solder melting temperature.

In the above, although specific embodiments of the present invention were detailed, these are only illustrations. In the present invention, various modifications and alterations of the specific embodiments illustrated above are included. The technical elements described in the present specification and the drawings can exhibit technical usefulness singularly or in various combinations thereof.

What is claimed is:

1. A semiconductor device comprising:
a semiconductor chip; and
a joined member, wherein
the semiconductor chip has a semiconductor substrate, a first electrode, and a second electrode,
the first electrode is arranged on a first surface of the semiconductor substrate,
the second electrode is arranged on a second surface of the semiconductor substrate,
the first electrode and the second electrode have larger linear expansion coefficients than a linear expansion coefficient of the semiconductor substrate,
the first electrode is joined to the joined member via a joint material, and
a tensile force in a surface direction of the first surface that is applied to the first surface of the semiconductor substrate from the first electrode due to thermal expansion of the first electrode at a melting temperature of the joint material is at least equal to a tensile force in the surface direction that is applied to the second surface of the semiconductor substrate from the second electrode due to thermal expansion of the second electrode at the melting temperature.

2. The semiconductor device according to claim 1, wherein
a thickness of the first electrode in a stacking direction of the semiconductor chip is at least equal to a thickness of the second electrode.

3. The semiconductor device according to claim 1, wherein
the linear expansion coefficient of the first electrode is at least equal to the linear expansion coefficient of the second electrode.

4. The semiconductor device according to claim 1, wherein
a front surface area of the first electrode in the surface direction is at least equal to a front surface area of the second electrode in the surface direction.

5. The semiconductor device according to claim 1, wherein
at least one of the first electrode and the second electrode is constituted by a single layer or plural layers.

6. The semiconductor device according to claim 1, wherein
the second electrode includes a first layer and a second layer,
the first layer includes a plurality of portions, the portions being arranged on the second surface of the semiconductor substrate and being separated from each other,
an insulation layer is arranged between the portions which are adjacent to each other,
the second layer covers an exposed surface of each of the portions of the first layer and at least part of an exposed surface of the insulation layer and is arranged over each of the portions of the first layer and the insulation layer, and
a linear expansion coefficient of the second layer is at most equal to a linear expansion coefficient of the first layer and a linear expansion coefficient of the insulation layer.

7. A method of manufacturing a semiconductor device comprising:
preparing a semiconductor substrate that is formed with a semiconductor element structure;
preparing a semiconductor chip by forming a first electrode on a first surface of the semiconductor substrate and by forming a second electrode on a second surface of the semiconductor substrate;
introducing a joined member on which the semiconductor chip is arranged into a furnace in a state that the first electrode of the semiconductor chip faces the first surface of the joined member via a joint material;
heating an inside of the furnace at least to a melting temperature of the joint material to melt the joint material;
cooling the joint member, on which the semiconductor chip is arranged, and hardening the joint material to join the first electrode of the semiconductor chip to the first surface of the joined member;
preparing the first electrode that is configured to apply a first tensile force due to thermal expansion of the first electrode to the first surface of the semiconductor substrate at the melting temperature of the joint material when the inside of the furnace is heated; and
preparing the second electrode that is configured to apply a second tensile force due to thermal expansion of the second electrode to the second surface of the semiconductor substrate at the melting temperature of the joint material when the inside of the furnace is heated, wherein
the first tensile force is at least equal to the second tensile force.

8. The method of manufacturing according to claim 7 further comprising:
constituting the second electrode by a first layer and a second layer;
constituting the first layer by a plurality of portions that are formed on the second surface of the semiconductor substrate and are separated from each other;
forming an insulation layer between the portions which are adjacent to each other;
forming the second layer of a material that has a linear expansion coefficient that is at most equal to linear expansion coefficients of materials of which the first layer and the insulation layer are respectively formed; and
covering an exposed surface of the first layer and at least part of an exposed surface of the insulation layer with the second layer by a mask sputtering method.
